(19) United States
(12) Patent Application Publication
(10) Pub. No.: US 2007/0117400 A1
(43) Pub. Date: May 24, 2007

(54) Substrate treating apparatus

(75) Inventors: Nobuaki Matsuoka, Kumamoto (JP); Yoshio Kimura, Kumamoto (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Minqto-Ku (JP)

(21) Appl. No.: 10/582,239

(22) PCT Filed: Nov. 11, 2004
(86) PCT No.: PCT/JP04/16723

§ 371 Date: Jun. 9, 2006

(30) Foreign Application Priority Data
Dec. 12, 2003 (JP) 2003-415467

(51) Int. Cl. H01L 21/31

(52) U.S. Cl. 438/758; 414/935

(57) ABSTRACT

A substrate processing apparatus capable of readily addressing an increase/decrease in quantity of substrates to be processed and a change in type thereof. The substrate processing apparatus includes a carrier block having a first transfer device performing delivery of the substrate with respect to a substrate carrier on a carrier placement portion, a transfer block provided adjacent to the carrier block and having a second transfer device, a first delivery stage performing delivery of the substrate between the first transfer device and the second transfer device, and a plurality of process blocks freely attachable/detachable with respect to the transfer block. Since the process blocks perform a series of processing on the substrate in units of the process blocks, it is readily possible to address considerable increase/decrease in quantity of processed substrates by attaching/detaching the process block(s), and to address the different change in type thereof by changing the process block(s).

### TECHNICAL FIELD

The present invention relates to a substrate processing apparatus that performs prescribed substrate processing, such as coating of a resist solution or developing after exposure to light, by applying a process solution on a surface of a substrate, such as a semiconductor wafer or an LCD substrate (glass substrate for liquid crystal display).

### BACKGROUND ART

In a manufacturing process of a semiconductor device, photolithography is used, where a substrate such as a semiconductor wafer (hereinafter, referred to as a “wafer”) is coated with a resist solution, and the resist film is exposed to light using a photo mask and then developed to thereby form a desired resist pattern on the substrate. Such processing is generally carried out using a substrate processing apparatus having a light exposure device connected to a coating and developing device used for coating of the resist solution and developing.

In order to reduce the area occupied by the apparatus while ensuring high throughput, the substrate processing apparatus is configured such that different kinds of processing, such as coating, developing, and heating/cooling, are performed on a substrate using separate units, and a required number of such units for each processing are incorporated in the apparatus. Transfer means for loading/unloading a substrate to/from each process unit is also provided.

An example of such a substrate processing apparatus will be described with reference to a configuration of Patent Document 1. In the figure, 11 represents a carrier stage 11 to/from which a carrier 10 containing 25 wafers W, for example, is loaded/unloaded. For example, three process blocks 12A, 12B, 12C are connected to carrier stage 11, and a light exposure device 12E is connected to the third process block 12C via an interface block 12D. Process blocks 12A, 12B, 12C include transfer means 13A, 13B, 13C, respectively, at the centers, and around the means, first and second process blocks 12A, 12B have coating units 14A, 14B, respectively, for coating a wafer with a coating solution, third process block 12C has a developing unit 15 for performing developing of the wafer after exposure to light, and all process blocks 12A-12C include shelf units 16A-16G provided with heating unit, cooling unit, delivery unit and others for performing prescribed heating or cooling processing on the wafer before or after the processing by coating unit 14 or developing unit 15.

In this apparatus, the wafers in carrier 10 on carrier stage 11 are taken out by a delivery arm 17, and transferred via a delivery unit of shelf unit 16A to first process block 12A, and then sequentially transferred to unoccupied process units in first and second process blocks 12A, 12B in a prescribed order to be subjected to the coating processing of the resist solution, and then transferred via process block 12C and interface block 12D to light exposure device 12E, where prescribed light exposure processing is performed. Thereafter, the wafers are again transferred to unoccupied process units in third process block 12C in a prescribed order to be subjected to the developing processing. Before and after the coating and developing processing, heating and cooling processing is carried out in unoccupied process units. Here, delivery of the wafers between first process block 12A and second process block 12B, between second process block 12B and third process block 12C, and between third process block 12C and interface block 12D is carried out via delivery units of shelf units 16C, 16E and 16G, respectively.

Patent Document 1: Japanese Patent Laying-Open No. 2000-124124 (see FIG. 2)

### DISCLOSURE OF THE INVENTION

Problems to be Solved by the Invention

The above-described coating and developing device is shipped as a device having processing capability consistent with the quantity of items to be processed by light exposure device 12E from the beginning. For example, the number of process units for each processing and arrangement of the process units are designed to ensure throughput considered in advance in accordance with the maximum processing capability of light exposure device 12E, and the maximum value of the quantity of items to be processed is set, e.g., to about 150 items per hour.

In practice, however, the quantity of items to be processed immediately after shipment of light exposure device 12E is about 50 items per hour, and with recent advance of the miniaturization process, condition setting of light exposure device 12E has become difficult, and more than one year is required for adjustment in order to increase the quantity of items to be processed to about 100 items per hour. This means that the coating and developing device is shipped as a device having processing capability of more than required level, which involves an excess initial investment, and hence, unnecessary investment at the time of shipping.

As such, in the coating and developing device as well, it would be practical to considerably increase the quantity of items to be processed from about 50 items per hour to about 100 items per hour in a stepwise manner, to be consistent with the throughput of light exposure device 12E. Practically in the coating and developing device, however, a series of processing are carried out using first through third process blocks 12A-12C as a whole, and therefore, transfer means 13A-13C provided at respective process blocks 12A-12C need to transfer the wafers not only within corresponding process blocks 12A-12C, but also transfer means 13A of first process block 12A needs to transfer wafers between first and second process blocks 12A and 12B, second process block 12B needs to transfer wafers between second and third process blocks 12B and 12C, and third process block 12C needs to transfer wafers between third process block 12C and interface block 12D. As the load of transfer means 13A-13C are thus large, if it is tried to increase the quantity of total items to be processed by the coating and developing device to about 100 items, customization would not be easy.

Further, the quantity of the items required to be processed differs in different manufacturers to which the device is to be shipped, and the baking processing in the heating unit and the developing time differ particularly. In the case where a series of processing is to be performed using first through third process blocks 12A-12C as a whole, as described above, the difference in processing time in each process unit would considerably affect the transfer program of transfer means 13A-13C, leading to complicated customization in quantity of processed items for each manufacturer. Still further, the coating and developing device has conventionally been used as a device dedicated to prescribed item type, and different devices have been prepared for different types of processing. However, recently there is a demand for a single device to handle production of various kinds of items in small quantities.

The present invention has been made in view of the foregoing circumstances, and an object of the present invention is to provide a substrate processing apparatus that can easily address the increase/decrease in quantity of substrates to be processed as well as the change in type thereof.

Means for Solving the Problems

Accordingly, the substrate processing apparatus of the present invention includes: a carrier block including a carrier placement portion to/from which a substrate carrier storing a plurality of substrates is loaded/unloaded, and first transfer means for performing delivery of the substrate with respect to the substrate carrier placed on the carrier placement portion; second transfer means provided adjacent to the carrier block and for transferring the substrate along a linear transfer path; a first delivery stage for performing delivery of the substrate between the first transfer means and the second transfer means; and a plurality of process blocks arranged along the transfer path and freely attachable/detachable with respect to a main body of the apparatus; wherein each process block includes a coating unit for applying a resist solution to the substrate, a developing unit for performing developing processing on the substrate after exposure to light, a heating unit for heating the substrate, third transfer means for transferring the substrate between the units, and a second delivery stage for performing delivery of the substrate between the second transfer means and the third transfer means, and wherein application of the resist solution to the substrate and/or the developing processing after exposure to light is performed in units of the respective process blocks.

Here, the substrate processing apparatus may be configured such that an interface portion to which a light exposure device is connected is connected to a side of the transfer path opposite to the side connected to the carrier block. Alternatively, it may be configured such that an interface portion to which a light exposure device is connected is connected to a side of the transfer path opposite to the side connected to the process blocks.

Another substrate processing apparatus according to the present invention includes: a carrier block including a carrier placement portion to/from which a substrate carrier storing a plurality of substrates is loaded/unloaded, and first transfer means for performing delivery of the substrate with respect to the substrate carrier placed on the carrier placement portion; second transfer means provided adjacent to the carrier block and for transferring the substrate along a linear transfer path; a first delivery stage for performing delivery of the substrate between the first transfer means and the second transfer means; and a plurality of process blocks arranged along the transfer path and freely attachable/detachable with respect to a main body of the apparatus; wherein each process block includes a liquid process unit performing processing with a chemical solution on the substrate, a heating unit for heating the substrate, third transfer means for transferring the substrate between the units, and a second delivery stage for performing delivery of the substrate between the second transfer means and the third transfer means, and wherein a series of processing are performed on the substrate in units of the respective process blocks. Here, the liquid process unit is for performing processing of forming a coating film, for example, and further, the liquid process unit is for applying a chemical solution including precursor of an insulating film to the substrate.

In such a substrate processing apparatus, the process block is provided to be freely attachable/detachable with respect to the main body of the apparatus, and a series of processing are performed on the substrate in units of process blocks. Thus, in the case where it is desired to considerably increase/decrease the quantity of the substrates to be processed, it is possible to address the situation by attaching/detaching the process block to/from the main body of the apparatus. Further, since the processing is completed in each process block, it is readily possible to address the change in type of items by changing the process block.

In the substrate processing apparatus according to the present invention, it is desirable that the plurality of process blocks are formed to have the same size in two dimensions. Further, it is desirable that the second transfer means is provided in a transfer block extending along arrangement of the plurality of process blocks, and that each process block is configured to be attachable/detachable with respect to the transfer block. Further, it may be configured to include a positioning member provided at a bottom portion or a side portion of a region where the process block is to be arranged, for use in positioning the process block. Alternatively, it may be configured to include a guide member provided at a bottom portion or a side portion of a region where the process block is to be arranged, for use in drawing the process block, and a positioning member provided for positioning the process block to the guide member.

Further, it may be configured such that each process block includes a plurality of utility lines for taking in utilities from the outside, and connection ends of the respective utility lines configured to be attachable/detachable with respect to connection ends of corresponding utility lines on the outside. Furthermore, the connection ends on the external side may be provided at a lower side of the second transfer means, and it may be configured such that when the process block is pressed to the second transfer means side, the connection ends on the external side are connected to the connection ends on the process block side. Further, the plurality of utility lines supply utilities different from each other, and each of the plurality of utility lines is branched on a downstream side to be guided to the respective process units. The plurality of utility lines include a supply line of liquid for temperature regulation, a supply line of inactive gas, an electric supply line, a signal line, and a chemical solution supply tube.

Effects of the Invention

According to the substrate processing apparatus of the present invention, it is readily possible to address an increase/decrease in quantity of the substrates to be processed and a change in type thereof.

### BRIEF DESCRIPTION OF THE DRAWINGS

FIG. 1 is a top plan view showing a substrate processing apparatus according to an embodiment of the present invention.

FIG. 2 is a perspective view showing the substrate processing apparatus according to the embodiment of the present invention.

FIG. 3 is a side cross sectional view of the substrate processing apparatus.

FIG. 4 is a side cross sectional view of the substrate processing apparatus.

FIG. 5 is a perspective view showing the interior of the process block of the substrate processing apparatus.

FIG. 6A illustrates connection of utility lines between the transfer block and the process block in the substrate processing apparatus.

FIG. 6B illustrates connection of the utility lines between the transfer block and the process block in the substrate processing apparatus.

FIG. 7 is a top plan view showing how a process block is added to the substrate processing apparatus.

FIG. 8A is a top plan view illustrating connection between the transfer block and the process block in the substrate processing apparatus.

FIG. 8B is a top plan view illustrating connection between the transfer block and the process block in the substrate processing apparatus.

FIG. 9 is a perspective view illustrating connection between the transfer block and the process block in the substrate processing apparatus.

FIG. 10 is a side view illustrating connection between the transfer block and the process block in the substrate processing apparatus.

FIG. 11 is a cross sectional view of a coating unit provided in the substrate processing apparatus.

FIG. 12 is a cross sectional view of a heating unit (PEB) provided in the substrate processing apparatus.

FIG. 13 is a perspective view of third transfer means provided in the substrate processing apparatus.

FIG. 14 is a top plan view illustrating another embodiment of the substrate processing apparatus of the present invention.

FIG. 15 is a side cross sectional view of the substrate processing apparatus.

FIG. 16 is a side cross sectional view of the substrate processing apparatus.

FIG. 17 is a top plan view illustrating another embodiment of the substrate processing apparatus of the present invention.

FIG. 18 is a top plan view of a conventional substrate processing apparatus.

FIG. 19 is a top plan view illustrating another embodiment of the substrate processing apparatus of the present invention.

### DESCRIPTION OF THE REFERENCE SIGNS

B1: carrier block; B2: transfer block; B3: first process block; B4: second process block; B5: interface portion; B6: light exposure device; C: substrate carrier; 22: first transfer means; 23: second transfer means; 24: delivery stage; 31: third transfer means; 32: coating unit; and 33: developing unit.

Best Modes for Carrying Out the Invention

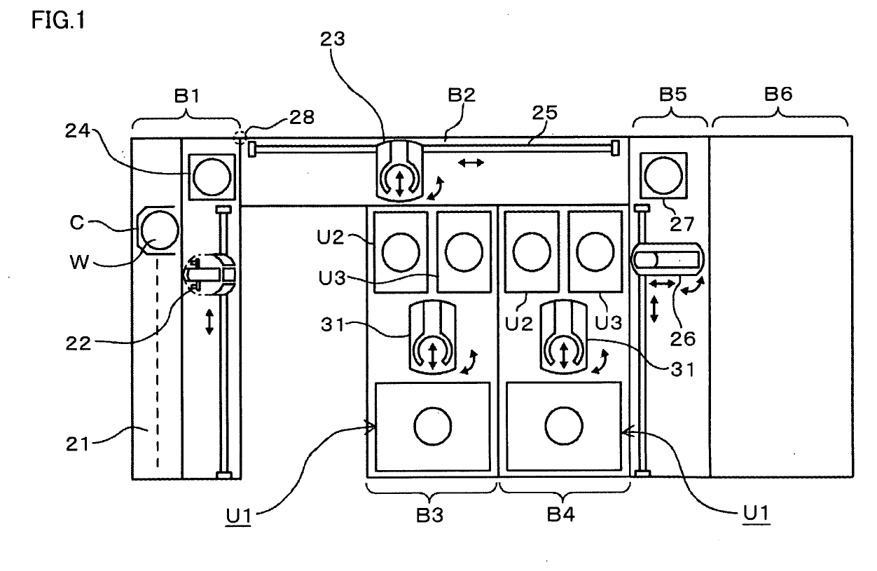

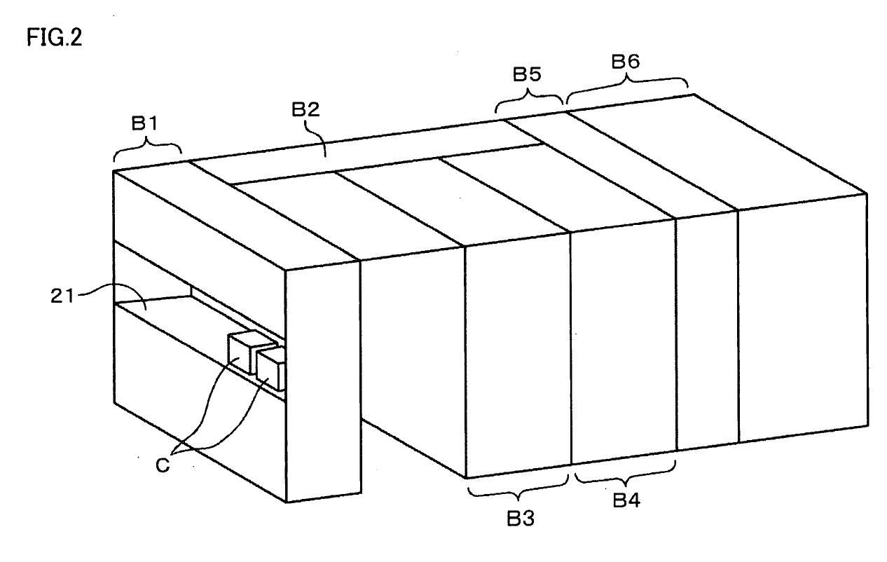

Hereinafter, an embodiment of a substrate processing apparatus of the present invention will be described. FIG. 1 is a top plan view showing an overall configuration according to an embodiment of the substrate processing apparatus, and FIG. 2 is a schematic perspective view thereof In the figures, B1 is a carrier block for loading/unloading a substrate carrier C containing, e.g., 25 substrates, such as semiconductor wafers W. Carrier block B1 includes a carrier placement portion 21 for placement of substrate carrier C, and first transfer means 22.

On one side of carrier block B1, for example on the left end side as seen from the carrier placement portion 21 side, a transfer block B2 having a transfer path linearly extending in the direction approximately orthogonal to the arrangement direction of carriers C is provided to be connected to carrier block B1. First transfer means 22 of carrier block B1 is configured to be movable left and right, back and forth, up and down and also rotatable about a vertical axis so as to take out a substrate G from substrate carrier C and deliver the relevant substrate G to second transfer means 23 of transfer block B2.

Here, a first delivery stage 24 is provided at carrier block B1 in the vicinity of the region connected to transfer block B2, for delivering wafer W between first transfer means 22 of carrier block B1 and second transfer means 23 of transfer block B2. This delivery stage 24 is configured in two stages of: a delivery stage for loading, for use in loading wafer W to transfer block B2; and a delivery stage for unloading, for use in unloading wafer W to transfer block B2. It is noted that delivery stage 24 may be provided in transfer block B2 in a region accessible by first transfer means 22. Alternatively, it may be configured in one stage so that a common delivery stage can be used for loading/unloading wafer W with respect to transfer block B2.

Transfer block B2 is provided with a guide rail 25 that constitutes the transfer path linearly extending in the direction approximately orthogonal to the arrangement direction of carriers C. Second transfer means 23 is provided with two holding arms for holding wafers W, for example, and is configured to be movable along guide rail 25 in the direction approximately orthogonal to the arrangement direction of carriers C, movable up and down, movable back and forth, and rotatable about a vertical axis.

Further, a plurality of process blocks are provided in a freely attachable/detachable manner with respect to transfer block B2 constituting the main body of the apparatus, which are arranged along the transfer path of transfer block B2. More specifically, at the back of carrier block B1, with a prescribed space being left, a first process block B3 and a second process block B4 as seen from the carrier block B1 side are connected to transfer block B2. In this example, process blocks B3 and B4 are identical to each other, with their parts arranged in identical layout. That is, process blocks B3 and B4 are formed to have the same size, and the equal numbers of identical kinds of process units are arranged in process blocks B3 and B4 in the same layout so as to perform the identical series of processing on wafers W.

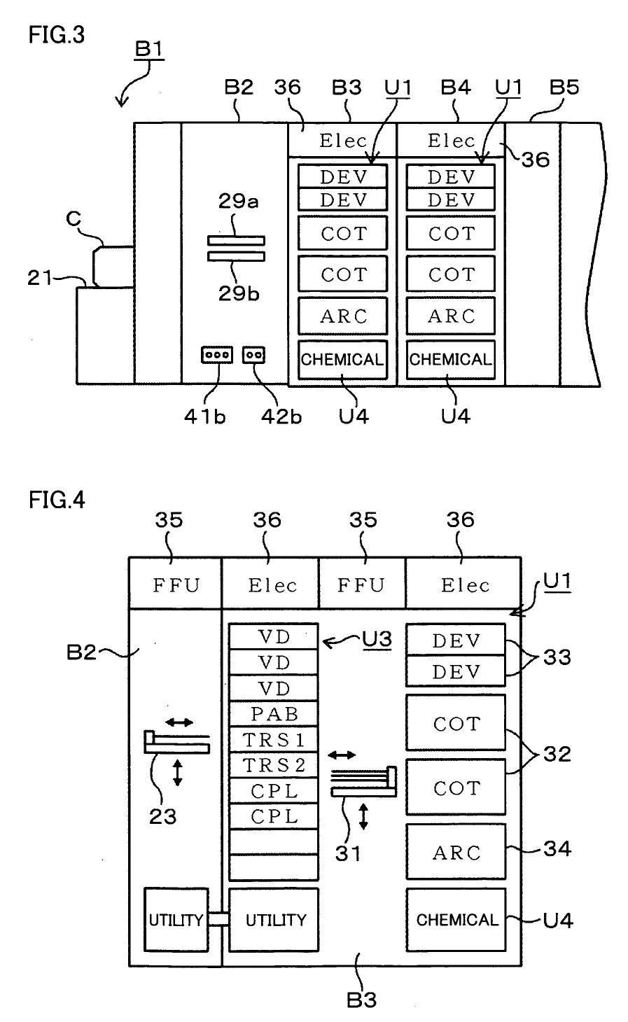

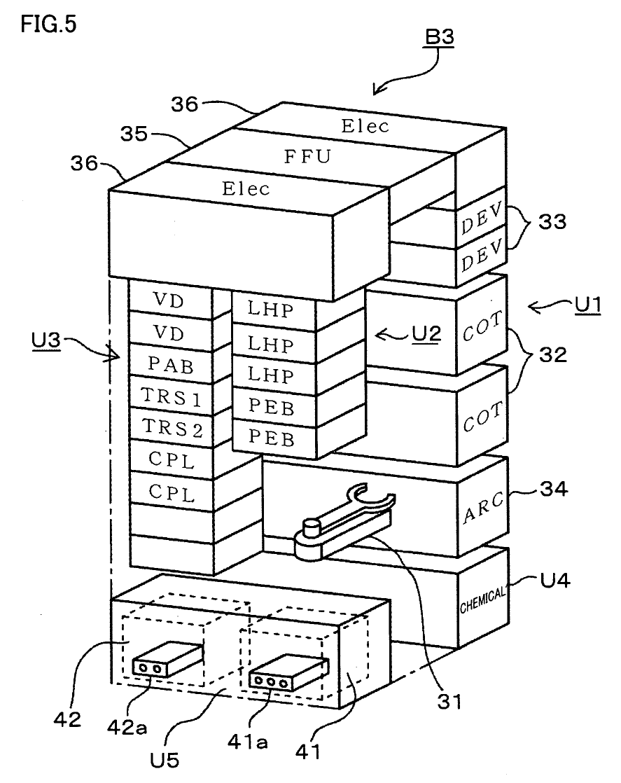

Specifically, taking first process block B3 as a representative and referring also to FIGS. 3, 4 and 5, third transfer means 31 is provided at the center of process block B3, and to surround the same, for example, a liquid process unit group U1 having for example two coating units (COT) 32, two developing units (DEV) 33, and one anti-reflection coating forming unit (ARC) stacked in multiple stages, e.g., in five stages, is arranged to the right as seen from carrier block B1 to the back, and shelf units U2 and U3 having multiple stages, e.g., six stages and ten stages, respectively, of units related to heating/cooling or the like, are arranged on the front side and the back side, respectively, to the left.

Coating unit 32, developing unit 33 and anti-reflection coating forming unit 34 each constitute the liquid process unit. Coating unit 32 is a unit for performing processing of coating wafer W with a resist solution, developing unit 33 is a unit for performing developing processing by, e.g., forming a puddle of a developing solution on the substrate after exposure to light and keeping the same in that state for a prescribed period of time, and anti-reflection coating forming unit 34 is a unit for forming an anti coating (Bottom-ARC) on the wafer surface before coating of the resist solution, for example. There is a case where after formation of the resist, an anti-reflection coating (Top-ARC) is formed on its surface.

Shelf units U2, U3 are each configured by stacking a plurality of units at the region accessible by second transfer means 23 of transfer block B2. In this example, there are provided for example three vacuum drying units (VD) for removing solvent included in the coating solution after the liquid processing performed at coating unit 32, anti-reflection coating forming unit 34 and others, for example four heating units (LHP) for performing prescribed heating processing on wafer W before coating with the resist solution, for example one heating unit (PAB), called a pre-baking unit or the like, for performing heating processing on the wafer after coating with the resist solution, for example two heating units (PEB), called a post-exposure baking unit or the like, for performing heating processing on the wafer W after exposure to light, for example two temperature regulating units (CPL) that are units for adjusting wafer W to a prescribed temperature, and additionally, for example one delivery unit (TRS1) for loading wafer W to process block B3, and for example one delivery unit (TRS2) for unloading wafer W from process block S1, which are allocated in a vertical direction.

These delivery units TRA1, TRS2 correspond to the second delivery stage of the present invention. Although FIGS. 3-5 show an example of the layout of these units, the number and the types of the units are not limited thereto, and in this example as well, it may be configured to have a single delivery unit to be used for both loading of wafer W to process block B3 and unloading of wafer W from process block B3.

Third transfer means 31 is configured to be movable up and down, back and forth, and also rotatable about a vertical axis, as will be described later, and is responsible for transferring substrate G between liquid process unit group U1 and shelf units U2, U3. It is noted that second transfer means 22 is not shown in FIG. 2 for the sake of convenience. Second transfer means 23 is configured to be movable in the horizontal direction in FIG. 1 along guide rail 25, movable up and down and back and forth, and rotatable about a vertical axis, as described above, so as to deliver wafer W received from first transfer means 22 to delivery unit TRS1 (TRS2) of process block B3.

Further, in this example, at each of the upper side of transfer block B2. and the upper side of the region of process block B3 where third transfer means 31 is provided, a fan filter unit (FFU) 35 formed with a fan having rotary blades and a ULPA filter or a chemical filter is provided. The cleaned air having particles and ammonia components removed by fan filter unit 35 is supplied to the lower side of transfer block B2 and to the lower side of the region where third transfer means 31 is provided. Further, at each of the upper side of the region in process block B3 where shelf units U2, U3 are provided, and the upper side of the region in process block B3 where liquid process unit group U1 is provided, an electric equipment storing portion (Elec) 36 is provided, in which a driver connected to a motor of transfer means or the like, an I/O board connected to each unit, and a control portion for controlling each unit are stored.

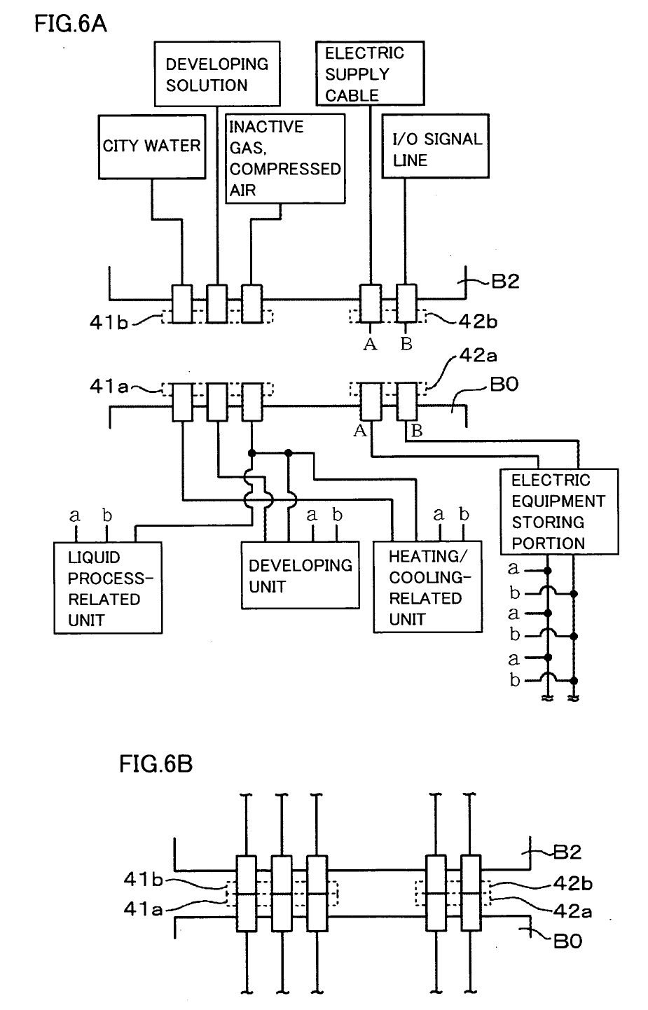

A chemical unit U4 storing tanks of chemical solutions such as a developing solution and a coating solution including an anti-reflection coating forming solution, a liquid for temperature regulation, a developing solution, inactive gas and others, is provided near the floor surface on the lower side of liquid process unit group U1, and near the floor surface on the lower side of shelf units U2, U3, a first utility unit U5 containing a plurality of utility lines for taking in utilities from the outside is provided. The plurality of utility lines are for supplying different utilities, which are each branched on the downstream side to be guided to the respective process units. More specifically, as shown in FIGS. 5, 6A and 6B for example, utility unit U5 is provided with a first utility line 41 including supply lines of city water serving as the liquid for temperature regulation, a chemical solution such as a developing solution, inactive gas and dry air, and a second utility line 42 including an electric supply line for activating heating/cooling-related units and liquid process-related units provided in process block B3, and signal lines such as I/O signal lines of INPUT/OUTPUT. Here, the tank of the chemical solution in chemical unit U4 is connected to first utility line 41.

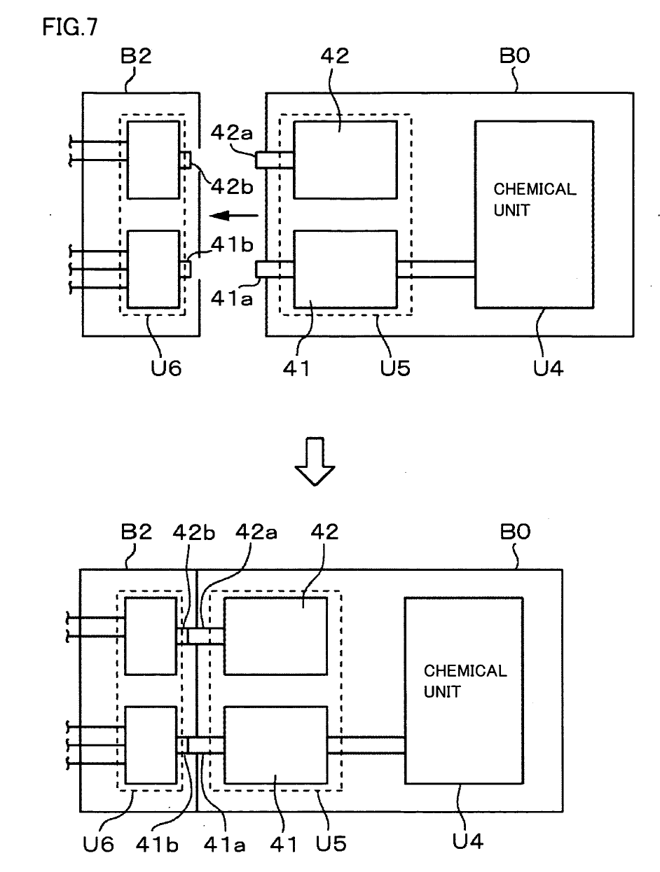

First and second utility lines 41, 42 have connection ends 41a, 42a, respectively, configured to be attachable/detachable to/from the connection ends of the corresponding external utility lines. Meanwhile, as shown in FIG. 7, transfer block B2 is provided with a second utility unit U6 of the external side, corresponding to first utility unit U5. This utility unit U6 has connection ends 41b, 42b of the external utility lines on the lower side of second transfer means 23 of transfer block B2 (see FIG. 3). Further, the multiple end side of connection ends 41b, 42b of the external utility lines of second utility unit U6 are respectively connected to the supply sources of city water, developing solution, inactive gas and dry air, electric supply cable, I/O signal line and others. When process block B3 is pressed to the second transfer means 23 side of transfer block B2, connection ends 41b, 42b on the external side (on the transfer block B2 side) are connected to connection ends 41a, 41b on the process block B3 side. Here, the utility lines on the transfer block B2 side are branched to the respective units via electric equipment storing portion 36.

The side of second process block B4 opposite to the first process block B3 side is connected via an interface portion B5 to a light exposure device B6. Further, interface portion B5 is set to be connected to the side of transfer block B2 opposite to the side connected to carrier block B1. Interface portion B5 is provided with delivery means 26, which is configured to be movable up and down, left and right, back and forth, and also rotatable about a vertical axis, for example, so as to deliver substrate G between second transfer means 23 of transfer block B2 and light exposure device B6. Here, at interface portion B5, in the vicinity of the region connected to transfer block B2, a delivery stage 27 formed in two stages for example is provided for delivering wafer W between delivery means 26 of interface portion B5 and transfer means 23 of transfer block B2. Delivery stage 27 may be provided in transfer block B2 in the region accessible by second transfer means 23 and by delivery means 26 of interface portion B5, or it may be configured with one stage.

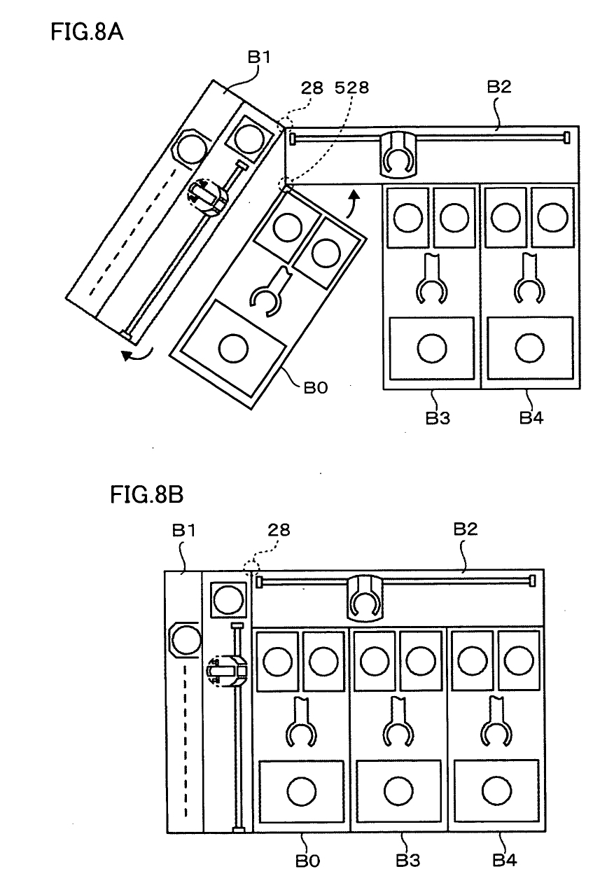

Further, in this example, the space between carrier block C and first process block B3 is configured as a space where one process block can be accommodated, which allows mounting of an additional process block B0. Here, carrier block B1 and transfer block B2 are connected via a rotation shaft 28. When installing additional process block B0, as shown in FIG. 8A, carrier block B1 is rotated via rotation shaft 28 to be separate from transfer block B2, and additional process block B0 is transferred in the state where transfer block B2 and carrier block B1 are separate from each other, and process block B0 is drawn toward transfer block B2 to establish connection between connection ends 41a, 42a of the utility lines on the process block B0 side and connection ends 41b, 42b of the utility lines on the transfer block B2 side, as described above (see FIG. 6A). Additional process block B0 is attached to transfer block B2 using a hinge 528, and then, carrier block B1 is returned to the original position such that carrier placement portion 21 is adjacent to transfer block B2 and additional process block B0, as shown in FIG. 8B. That is, carrier block B1 is capable of rotating about rotation shaft 28 provided at the end of transfer block B2. Process blocks B0, B3 and B4 are attached to transfer block B2 via hinge 528, and rotated about hinge 528 to be positioned in place.

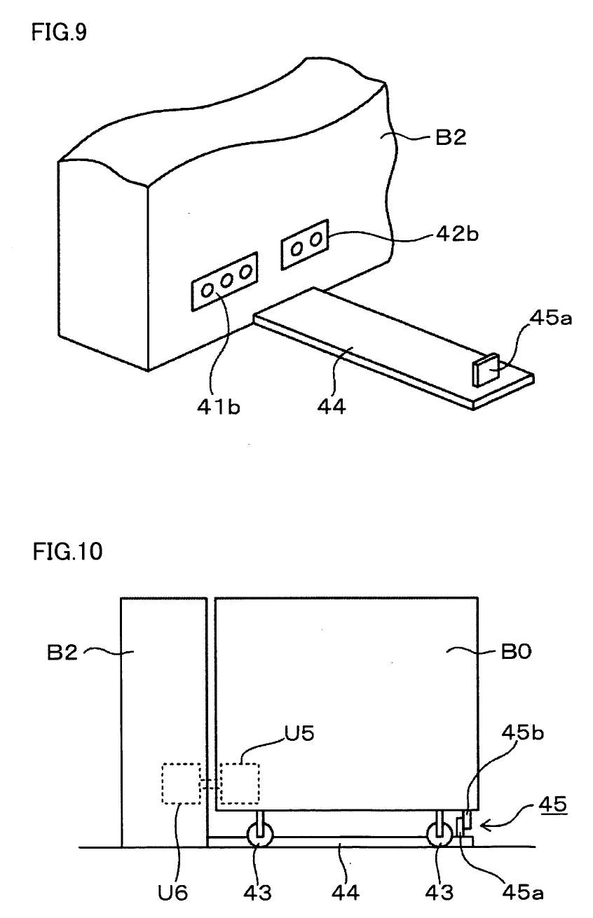

In this case, as shown in FIGS. 9 and 10 for example, on the lower end side of process block B0, casters 43 are attached at the front side and the back side in the traveling direction of process block B0 (in the direction advancing toward the transfer block B2 side), at both sides in the width direction as seen from the traveling direction. On the bottom side of transfer block B2, a guide plate 44 serving as a guide member is provided, which is narrower than the distance between casters 43 arranged in the width direction, to allow casters 43 to travel on the both sides of guide plate 44. Further, on the loading side (front side) of guide plate 44 and the loading side (front side) on the lower end side of process block B0, securing members 45 (45a, 45b) are provided, which can be engaged in one step when process block B0 is attached to transfer block B2. Securing members 45 also serve as positioning members.

In this example, when additionally installing process block B0, for example process block B0 is pulled such that casters 43 move along the respective ends of guide plate 44, and when process block B0 and guide plate 44 are positioned by securing members 45 and connected by engagement, connection ends 41a, 42a of the utility lines on the process block B0 side and connection ends 41b, 42b of the utility lines on the external (transfer block B2) side are connected collectively. It is noted that guide plate 44 and securing member 45 provided for pulling in process block B0 may be provided at the side portion of carrier block B1 or first process block B3 to be adjacent to process block B0.

In FIG. 3, 29a, 29b represent loading ports of wafer W formed at positions in transfer block B2 corresponding to delivery units TRS1, TRS2 of process block B0. Second transfer means 23 of transfer block B2 delivers wafer W via loading ports 29a, 29b into process block B0.

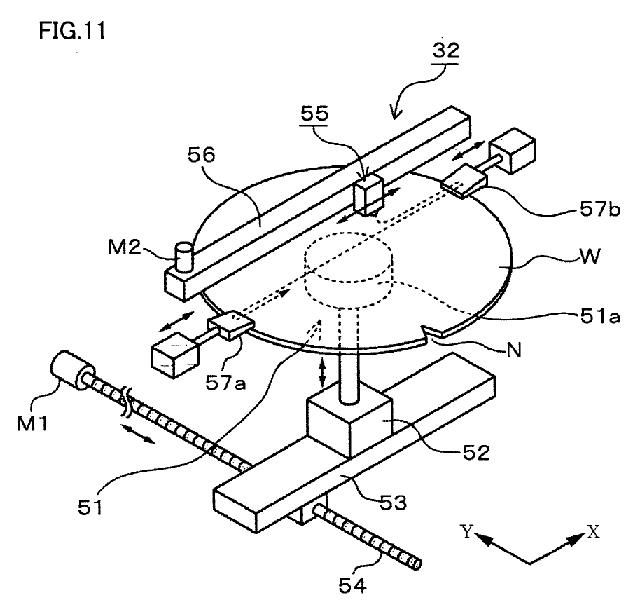

Hereinafter, configurations of coating unit 32 and heating unit (PEB) and others provided at process blocks B3, B4 will be described in brief Firstly, coating unit 32 is described with reference to FIG. 11. Although the coating unit used may be a known device of a spin coating type where a processing solution is supplied onto the substrate and spread by rotation, herein, a scanning coating device is described by way of example. Wafer W is partially notched at its peripheral portion to provide a notch N indicating the direction of wafer W. In the figure, 51 represents a substrate holding portion, which is configured with an attraction portion 51a that attracts the back surface side of wafer W to hold it approximately horizontally, and a drive base body 52, movable in the X direction, that causes attraction portion 51a to be movable up and down and rotatable about a vertical axis. Drive base body 52 has its bottom end supported by a movable body 53.

A ball screw portion 54 is provided near the bottom surface of movable body 53, which portion is driven by a motor M1. When ball screw portion 54 is rotated by motor M1, movable body 53 is guided by a rail not shown, to move in the Y direction in the figure. Further, a rail not shown is provided on the upper surface of movable body 53 to guide drive base body 52 in the X direction. With the operations of drive base body 52 and movable body 53, wafer W held by substrate holding portion 51 is movable to any position in the X and Y directions, respectively. By means of movable body 53, the rails not shown, ball screw portion 54 and motor M1, wafer W is moved back and forth relative to a coating solution nozzle 55 provided on the upper side of wafer W, i.e., wafer W is moved in the Y axis direction in FIG. 11.

Coating solution nozzle 55 is configured to be movable in the X direction by means of a drive base body 56 of a rectangular shape extending in the X direction, which contains therein a drive pulley, a driven pulley, an endless belt wound around the pulleys, which are not shown, and a motor M2 for rotating the drive pulley. In the figure, 57 (57a, 57b) represents a pair of liquid receiving portions for receiving the coating solution dropping from the above to prevent the coating solution from being fed to the region of wafer W near the outer periphery.

In this coating unit 32, when coating solution nozzle 55 moves from one end face to the other end face of the wafer, wafer W is moved intermittently, at the corresponding timing, in the direction crossing the same. With repetition of such an operation, the coating solution is applied onto wafer W as if drawing a picture without lifting the pencil from the paper.

Anti-reflection coating forming unit 34 is configured similarly to coating unit 32, for example. The vacuum drying unit (VD), which is the process unit for use in the step following that of coating unit 32, is configured to heat wafer W to a prescribed temperature while reducing the pressure to a prescribed degree of vacuum in a sealed vessel, for example, to vaporize a solvent within the coating film to thereby form the coating film. Further, developing unit 33 is configured to supply a developing solution from the supply nozzle to the central portion of wafer W along the width in the radial direction of wafer W, to cause wafer W to half turn to create a puddle of the developing solution on wafer W, and to carry out prescribed developing processing by leaving wafer W with the puddle of the developing solution thereon for a prescribed period of time.

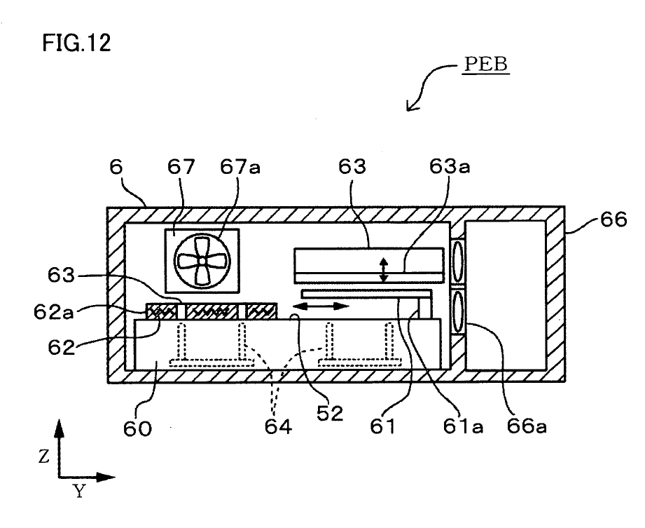

A post exposure baking unit (PEB) serving as the heating unit will now be described with reference to FIG. 12. In a casing 6, on an upper surface of a stage 60, a cooling plate 61 is arranged on the front side, and a heating plate 62 provided with a heater 62a is arranged on the back side. Cooling plate 61 is used to deliver wafer W between heating plate 62 and third transfer means 31 that advances into casing 6 via an opening portion 63 provided with a shutter 63a, and also functions to cool the heated wafer W to some extent (rough heat removal) at the time of transfer. Thus, as shown in the figure, a leg portion 61a is configured to be movable back and forth in the Y direction along guide means not shown, so that cooling plate 61 can move from the position on the side of opening portion 63 to the position above heating plate 62. Further, a cooling flow channel not shown is provided on the rear surface of cooling plate 61.

In stage 60, at the delivery position of wafer W between third transfer means 31 and cooling plate 61, and at the delivery position of wafer W between heating plate 62 and cooling plate 61, support pins 64 are provided, which protrude and retreat freely. Cooling plate 61 is provided with slits not shown, to allow raised support pins 64 to penetrate through cooling plate 61 to lift wafer W. In the figure, 66 represents a ventilation room in communication via a fan 66a, and 67 represents a ventilation hole provided with a fan 67a.

In such a heating unit (PEB), wafer W is delivered from third transfer means 31 onto cooling plate 61, and then delivered by cooling plate 61 onto heating plate 62, where prescribed heating processing is carried out. The wafer having undergone the heating processing is returned from heating plate 62 to cooling plate 61, where it is cooled to some extent, and then received by the third transfer means to be transferred to the next step.

The other heating units (LHP), (PAB) each have a configuration provided with only a heating plate for heating wafer W to a prescribed temperature, and temperature regulating unit (CPL) has a configuration provided with only a cooling plate for adjusting wafer W to a prescribed temperature.

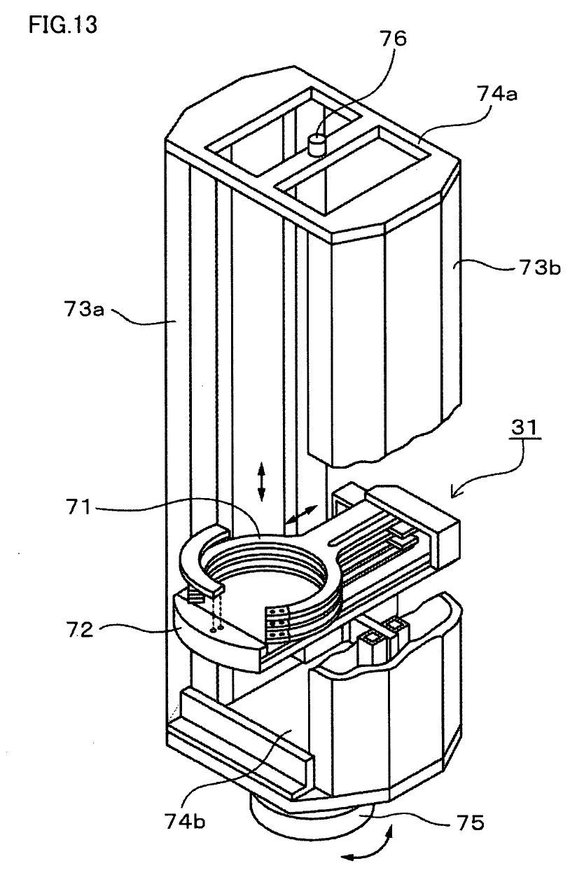

Third transfer means 31 will now be described with reference to FIG. 13. This transfer means 31 is provided with for example three arms 71 for holding wafers W, a base table 72 supporting arms 71 to be freely movable back and forth, a pair of guiding rails 73a, 73b supporting base table 72 to be freely movable up and down, connecting members 74a, 74b respectively connecting the upper ends and lower ends of guiding rails 73a , 73b , a rotation drive portion 75 integrally attached to connecting member 74b at the lower ends of the guiding rails so as to drive a frame body made of guiding rails 73a, 73b and connecting members 74a, 74b in a manner rotatable about a vertical axis, and a rotation shaft portion 76 provided at connecting member 74a at the upper ends of the guiding rails.

Arm 71 is configured with three stages so as to respectively hold wafers W, and has its proximal end portion movable in a sliding manner along the longitudinal direction of the base table. Such back and forth movement of arm 71 by sliding is controlled by drive means not shown. Further, the up and down movement of base table 72 is controlled by another drive means not shown. In this manner, arm 71 is driven to be rotatable about the vertical axis as well as movable up and down and back and forth.

The flow of the wafers in such a substrate processing apparatus will now be described taking the case of forming coating films of the same kind for wafers W in first process block B3 and second process block B4 as an example. An automatic transfer robot (or an operator) loads carrier C storing 25 wafers W, for example, from the outside onto carrier placement portion 21 of carrier block B1. Next, first transfer means 22 takes out the n-th wafer W from within carrier C and delivers the same to delivery stage 24 of carrier block B1. Wafer W on delivery stage 24 is delivered by second transfer means 23 of transfer bock B2 via delivery unit TRS1 of first process block B3, for example, to third transfer means 31. Similarly, the (n+1)-th wafer W within carrier C is delivered to third transfer means 31 via delivery stage 24 of carrier block B1, second transfer means 23 of transfer block B2, and via delivery unit TRS1 of second process block B4, for example. In this manner, wafers W within carrier C are delivered sequentially to first process block B3 and second process block B4, for example.

Since processing of the same kind, e.g., resist film forming processing, is carried out in units of blocks in first and second process blocks B3 and B4 in this example, the flow of wafer W within process block B3 will be explained taking first process block B3 as an example. Firstly, wafer W on delivery unit TRS1 is transferred by third transfer means 31 in the order of temperature regulating unit (CPL)→anti-reflection coating forming unit (Bottom-ARC) 34→vacuum drying unit (VD), to form an anti-reflection coating, and thereafter, the wafer is transferred in the order of heating unit (LHP)→temperture regulating unit (CPL)→coating unit 32→vacuum drying unit (VD), to perform coating processing of a resist solution. At this time, in the case of using a conventional spin coating device, the vacuum drying unit (VD) does not necessarily have to be provided depending on the conditions.

After prescribed heating processing is carried out in heating unit (PAB), wafer W is delivered to second transfer means 23 of transfer block B2 via delivery unit TRS2 for output, and then delivered by second transfer means 23 to delivery stage 27 of interface portion B5. Thereafter, wafer W is transferred by delivery means 26 of interface portion B5 to light exposure device B6, where prescribed light exposure processing is carried out.

Wafer W having been exposed to light is transferred via delivery means 26 of interface portion B5, delivery stage 27, and second transfer means 23 of transfer block B2, back to the original process block where the resist solution was applied, i.e., to first process block B3 via delivery unit TRS1 for input provided at process block B3. It is then transferred by third transfer means 31 in the order of heating unit (PEB)→temperature regulating unit (CPL)→developing unit 33, where prescribed developing processing is carried out. Thereafter, it is adjusted to a prescribed temperature by heating unit (LHP), and delivered to second transfer means 23 of transfer block B2 via delivery unit TRS2 for output. It is then returned to original carrier C, for example, via delivery stage 24 of carrier block B1 and first delivery means 22.

Similarly, wafer W having been applied with an anti-reflection coating and a resist solution in second process block B4 is transferred by second transfer means 23 of transfer block B2 via interface portion B5 to light exposure device B6, where prescribed light exposure processing is carried out. Thereafter, it is returned via interface portion B5 and second transfer means 23 to the original process block where the resist solution was applied, i.e., to second process block B4, where developing processing is carried out. Thereafter, it is returned to carrier block B1 via second transfer means 23 of transfer block B2 and first transfer means 22.

Thus, in this example, wafer W having been applied with the resist solution in first process block B3 (or second process block B4) is subjected to the developing processing in the relevant block B3 (B4), so that formation of coating film of one type is carried out in units of blocks in first and second process blocks B3, B4, and formation of the coating film is completed in the respective process blocks B3, B4.

In this configuration, transfer block B2 is provided, and second transfer means 23 of the relevant transfer block B2 performs delivery of wafers W between carrier block B1 and respective process blocks B3, B4, and between respective process blocks B3, B4 and interface portion B5. Further, in the respective process blocks B3, B4, parallel processing is carried out for each block. This means that third transfer means 31 of each process block B3, B4 only needs to take charge of transfer of wafer W within the relevant process block B3, B4, so that the burden of transfer means 31 is alleviated compared to the conventional case. As such, it is less probable that transfer of processed wafer W by transfer means 31 is awaited, which leads to reduction in transfer time and, hence, improvement in throughput of the entire apparatus.

Further, the process block is configured to be freely attachable to and detachable from transfer block B2 (main body of the apparatus). Thus, it is possible to arrange one or two process blocks at the time of shipment, and a process block may be added in accordance with adjustment of the quantity of items to be processed in light exposure device B6. More specifically, although the case of increasing the quantity of items to be processed in a process block by about 10 items per hour may be addressed by adjustment in each process block, it is difficult to address the case of increasing the quantity by about 50 items per hour. However, since the quantity of items to be processed in one process block is about 50 items, the total quantity of items to be processed in the whole process blocks can considerably be increased in a stepwise manner from 50 items→100 items→150 items or the like by adding the process block itself, without the need of drastic change of the apparatus. Accordingly, it is possible to minimize the initial investment at the time of shipment as well as the time required for changing the apparatus in response to the increase in quantity of items to be processed.

Further, since the processing of one kind is completed in units of process blocks, adjustment and condition setting can be performed in advance before shipment. This can reduce trouble and time of the on-site adjustment work upon installation of an additional process block.

Still further, even in the case where the quantity of items required to be processed differs for each manufacturer to which the apparatus is to be shipped, particularly in the case where baking processing in the heating unit or the like differs, the processing is completed in units of process blocks, and thus, all that is needed is to take account of the transfer program of transfer means 31 within the relevant process block. Thus, compared to the conventional case where a series of processing are carried out in first through third process blocks 12A-12C as a whole, the influence of the difference in processing time in each process unit on transfer means 31 is small, so that it is readily possible to perform customization of the quantity of items to be processed for each manufacturer.

When adding a process block, connection ends 41a, 42a of the utility lines on the process block side can be connected collectively to connection ends 4lb, 42b of the utility lines on the external (transfer block) side as described above, which facilitates the connecting job of the utility systems upon installation of an additional process block.

In the present embodiment, the case of performing processing of the same kind in a plurality of process blocks has been described. Alternatively, processing of different kinds may be carried out in the respective process blocks.

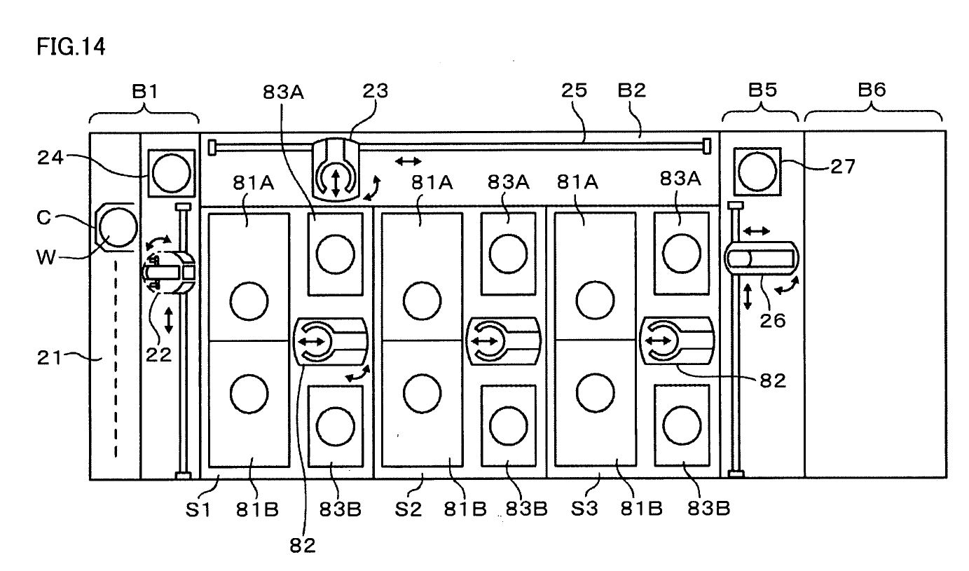

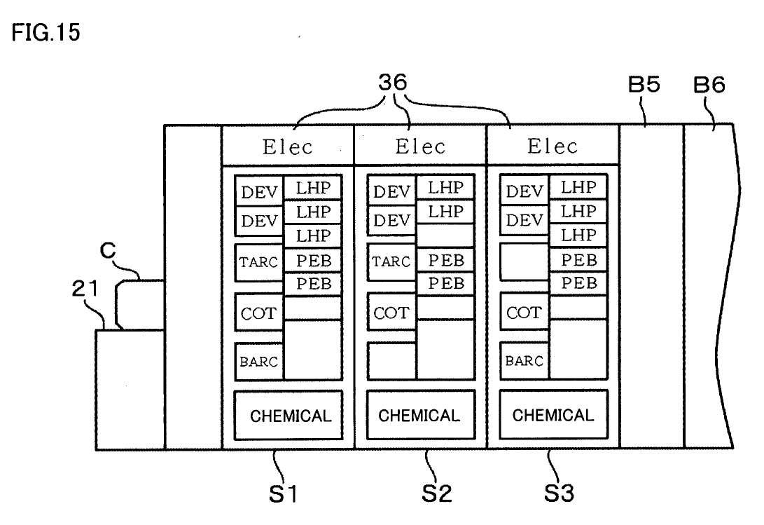

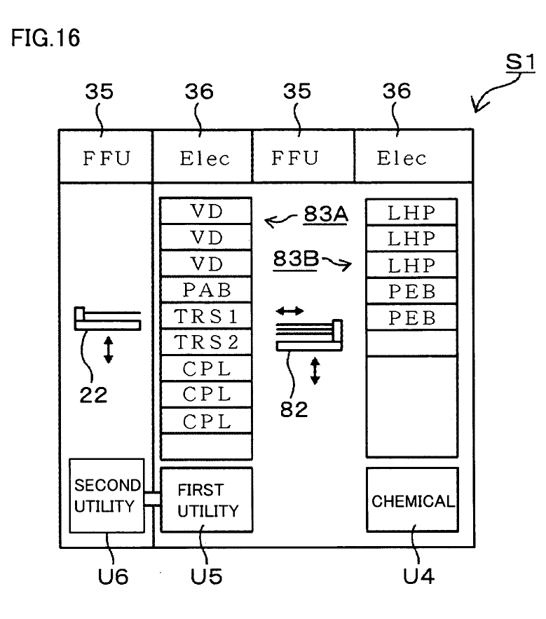

Further, the substrate processing apparatus of the present invention may be configured as shown in FIGS. 14-16. The substrate processing apparatus of this example differs from that of the above-described example only in the internal configuration of first through third process blocks S1-S3. This substrate processing apparatus will now be described taking the case of performing processing of different kinds in a plurality of process blocks S1-S3 as an example. Three process blocks S1-S3 are formed to have the same size and the same layout of process units arranged therein, although a series of processing of different kinds are performed on wafer W in each block.

More specifically, from the front side as seen from carrier block B1, two liquid process unit groups 81A, 81B each having liquid process-related process units in multiple stages, e.g., five stages, are provided, and on the back side thereof, two shelf units 83A, 83B each having heating/cooling-related process units in multiple stages, e.g., ten stages and six stages, respectively, are provided, with third transfer means 82 sandwiched therebetween. Third transfer means 82 delivers wafers W between liquid process unit groups 81A, 81B and shelf units 83A, 83B. Further, shelf unit 83A on the transfer block B2 side is provided with a delivery unit (TRS1, TRS2) at the position accessible by second transfer means 23 of transfer block B2, serving as the delivery stage for delivering wafers W between second transfer means 23 and third transfer means 82.

In first process block S1, in order for the processing of forming, e.g., the lower-layer anti-reflection coating (BARC), the resist film and the upper-layer anti-reflection coating (TARC) to be performed on wafer W, for example one lower-layer anti-reflection coating forming unit (BARC), one coating unit (COT), one upper-layer anti-reflection coating forming unit (TARC),and two developing units (DEV) are arranged in liquid process unit groups 81A, 81B, and in shelf units 82A, 82B, for example three vacuum drying units (VD), for example three heating units (LHP), for example one heating unit (PAB), for example two heating units (PEB), for example three temperature regulating units (CPL), and additionally, two delivery units (TRS1, TRS2) are arranged in a vertical direction.

In second process block S2, in order for the processing of forming, e.g., the resist film and the upper-layer anti-reflection coating to be performed on wafer W, for example one coating unit (COT), one upper-layer anti-reflection coating forming unit (TARC) and two developing units (DEV) are arranged in liquid process unit groups 81A, 81B, and in shelf units 82A, 82B, for example one hydrophobic process unit (ADH), two vacuum drying units (VD), for example two heating units (LHP), for example one heating unit (PAB), for example two heating units (PEB), for example three temperature regulating units (CPL), and additionally, for example two delivery units (TRS1, TRS2) are arranged in a vertical direction.

In third process block S3, in order for the processing of forming, e.g., the lower-layer anti-reflection coating and the resist film to be performed on wafer W, for example one coating unit (COT), one lower-layer anti-reflection coating forming unit (BARC), and two developing units (DEV) are arranged in liquid process unit groups 81A, 81B, and in shelf units 82A, 82B, for example two vacuum drying units (VD), for example three heating units (LHP), for example one heating unit (PAB), for example two heating units (PEB), for example three temperature regulating units (CPL), and additionally, for example two delivery units (TRS1, TRS2) are arranged in a vertical direction. The other configuration is identical to that of the above-described substrate processing apparatus shown in FIG. 1.

The flow of wafers W in this substrate processing apparatus will now be explained, taking the case where wafer W1 to be subjected to first processing, wafer W2 to be subjected to second processing and wafer W3 to be subjected to third processing are stored in the same carrier C as an example. Firstly, wafer W1 to be subjected to the first processing is taken out by first transfer means 22 from within carrier C1 loaded to carrier placement portion 21 of carrier block B1, and is delivered to delivery stage 24 of carrier block B1.

Wafer W on this delivery stage 24 is delivered by second transfer means 23 of transfer block B2 via delivery unit TRS1 of shelf unit 83A of first process block S1 to third transfer means 31, for example, and in process block S1, it is transferred in the order of, e.g., temperature regulating unit (CPL)→lower-layer anti-reflection coating forming unit (BARC)→vacuum drying unit (VD), to form the lower-layer anti-reflection coating, and thereafter, it is transferred in the order of heating unit (LHP)→temperature regulating unit (CPL)→coating unit→vacuum drying unit (VD), to perform the resist solution coating processing. Thereafter, it is transferred in the order of heating unit (PAB)→temperature regulating unit (CPL)→upper-layer anti-reflection coating forming unit (TARC)→vacuum drying unit (VD)→heating unit (LHP), to form the upper-layer anti-reflection coating, and then transferred along the path of delivery unit TRS2 for output→second transfer means 23 of transfer block B2 →delivery stage 27 of interface portion B5→delivery means 26→light exposure device B6, where prescribed light exposure processing is carried out.

Next, wafer W having been exposed to light is transferred along the path of delivery means 26 of interface portion B5→delivery stage 27→second transfer means 23, back to the original process block where the resist solution was applied, i.e., first process block S1 via delivery unit TRS1 for input of the relevant process block S1, where it is transferred to heating unit (PEB)→temperature regulating unit (CPL)→developing unit (DEV), to be subjected to prescribed developing processing, and then is adjusted to a prescribed temperature at heating unit (LHP). Wafer W having thus undergone the first processing of forming the lower-layer anti-reflection coating, the resist film and the upper-layer anti-reflection coating, is returned to the original carrier C, for example, along the path of delivery unit TRS2 for output→second transfer means 23→delivery stage 24 of carrier block B1→first delivery means 22.

Further, wafer W2 taken out of the same carrier C to be subjected to the second processing is delivered by second transfer means 23 via delivery stage 24 of carrier block B1 to third transfer means 31 of second process block S2 via delivery unit TRS1 for example, and in process block S2, it is transferred in the order of, e.g., hydrophobic process unit (ADH)→temperature regulating unit (CPL)→coating unit (COT)→vacuum drying unit (VD), to be subjected to resist solution coating processing. Thereafter, it is transferred in the order of heating unit (PAB)→temperature regulating unit (CPL)→upper-layer anti-reflection coating forming unit (TARC)→vacuum drying unit (VD)→heating unit (LHP), to form the upper-layer anti-reflection coating, and then transferred along the path of delivery unit TRS2 for output→second transfer means 23 of transfer block B→delivery stage 27 of interface portion B5→delivery means 26→light exposure device B6, where prescribed light exposure processing is carried out.

Thereafter, wafer W having been exposed to light is transferred along the path identical to the case of the above-described first processing, to second process block S2 where the coating of the resist solution and formation of the upper-layer anti-reflection coating were carried out, and is subjected to prescribed developing processing. Wafer W having thus undergone the second processing of forming the resist film and the upper-layer anti-reflection coating is returned to the original carrier C, for example.

Further, wafer W3 taken out from the same carrier C to be subjected to the third processing is delivered by second transfer means 23 via delivery stage 24 of carrier block B1 to third transfer means 31 via delivery unit TRS1 of third process block S3 for example, and in process block S3, it is transferred in the order of, e.g., temperature regulating unit (CPL)→lower-layer anti-reflection coating forming unit (BARC)→vacuum drying unit (VD)→heating unit (LHP), to form the lower-layer anti-reflection coating, and then transferred in the order of temperature regulating unit (CPL)→coating unit (COT)→vacuum drying unit (VD)→heating unit (PAB), to be subjected to the resist solution coating processing. Thereafter, it is transferred along the path of delivery unit TRS2 for output→second transfer means 23 of transfer block B→delivery stage 27 of interface portion B5→delivery means 26→light exposure device B6, where prescribed light exposure processing is carried out.

Next, wafer W having been exposed to light is transferred along the path identical to the case of the above-described first processing, to third process block S3 where the coating of resist solution and formation of the lower-layer anti-reflection coating were carried out, where prescribed developing processing is carried out, and then, wafer W having thus undergone the third processing of forming the lower-layer anti-reflection coating and the resist film is returned to the original carrier C, for example.

It is noted that in the above-described first through third processing as well, if a configuration of spin coating type is used as the coating unit, the processing in the vacuum drying unit (VD) does not necessarily have to be carried out.

In this configuration, a series of processing of different kinds are completed in units of process blocks B, and thus, the case of expanding the kinds of items can be addressed by adding a process block B corresponding to the new kind of item, which ensures a great degree of freedom of processing carried out in the relevant apparatus. Accordingly, it is possible to address the production of various kinds of items in small quantities as in the case of, e.g., mounting wafers to be subjected to different kinds of processing in the same carrier C, as explained in the above embodiment.

It is also possible to set such that processing of different kinds is carried out for different carriers C. In this case, carrier C1 storing wafer W1 to be subjected to first processing, carrier C2 storing wafer W2 to be subjected to second processing, and carrier C3 storing wafer W2 to be subjected to third processing may be placed on carrier placement portion 21, for example, and first transfer means 22 may take out wafers W1-W3 sequentially from carriers C1-C3, and second transfer means 23 may transfer them to corresponding process blocks C1-C3, and after prescribed processing is carried out in the respective process blocks S1-S3, the wafers may be returned to the corresponding original carriers C1-C3 by second transfer means 23 and first transfer means 22. It is noted that delivery stage 27 may be provided with a temperature regulating function for keeping wafer W at a uniform substrate temperature before delivery, or a plurality of stages may be provided.

In the present embodiment, process blocks having lower-layer anti-reflection coating forming units (BASC), coating units (COT), upper-layer anti-reflection coating forming units (TARC), vacuum drying units (VD), heating units (LHP), heating units (PAB), heating units (PEB), temperature regulating units (CPL), and delivery units (TRS1, TRS2) arranged in the same number and in the same layout may be prepared as process blocks S1-S3, for example, and the required process units may be used in each of process blocks S1-S3. In this case, the respective process units are mounted in advance in the maximum required number.

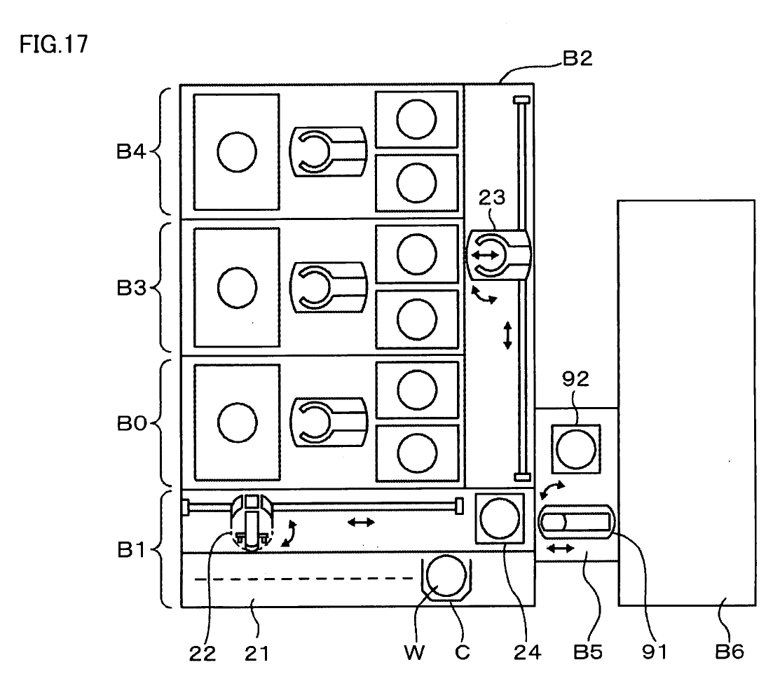

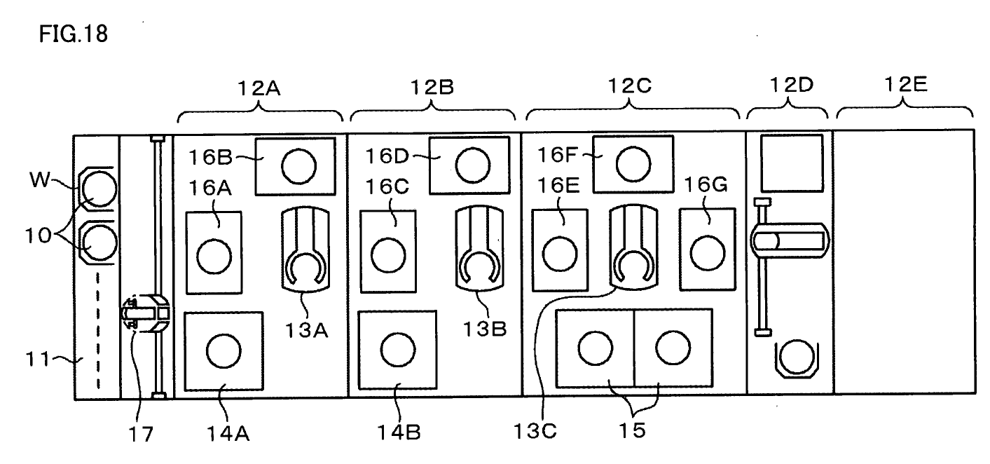

Further, the substrate processing apparatus of the present invention is not limited to the configuration where light exposure device B6 is connected via interface portion B5 to the side of transfer block B2 opposite to the side connected to carrier block B1. It may be configured as shown in FIG. 17 for example, such that light exposure device B6 is connected via interface portion B5 to the side of transfer block B2 opposite to the side connected to process blocks B0, B3, B4. In this case, as shown in FIG. 17 for example, interface portion B5 is provided with a delivery stage 92 for delivering wafers W between second transfer means 23 of transfer block B2 and delivery means 91 of interface portion B5. Here, the layout in each process block may be as shown in FIG. 1, or as shown in FIG. 14.

Further, in the present invention, the apparatus capable of accommodating three process blocks may be shipped in the state where two process blocks are connected, and another process block may be added later in response to an increase in quantity of items to be processed. Alternatively, it may be configured to mount two or three process blocks, without providing an empty space for a process block from the beginning. Even in the configuration not provided with an empty space for a process block, it is possible to add a new process unit in later stage. In such a case, although it is necessary to extend the transfer path when adding the new process block to shift the position of the light exposure device, the light exposure device using electron beam (EB) can be moved later, so that this manner is effective as well.

Still further, in the present invention, it may be configured such that process blocks are allocated corresponding to lots of wafers W, and wafers W may be transferred to the respective process blocks such that wafers W of the first lot are processed at first processing bock B3 and wafers W of the second lot are processed at second process block B4.

In the present invention, besides the configuration where the light exposure device is connected to the process block(s), the light exposure device may be separated from the process block(s) and provided at a different location. In this case, wafer W in carrier C of carrier block B1 is transferred via first and second transfer means to a prescribed process block to be subjected to resist solution coating processing, for example, and then returned to carrier block B1 again via the second and first transfer means, and thereafter, the relevant wafer W is transferred to the light exposure device arranged at the different location to be subjected to prescribed light exposure processing. Wafer W having undergone the light exposure processing is returned via carrier block B1 and the first and second transfer means to the original process block where the resist solution was applied, and prescribed developing processing is carried out therein. It is then again returned via the second and first transfer means to the original carrier C within carrier block B1.

Further, in the substrate processing apparatus of the present invention, a heating unit (PEB) may be mounted in interface portion B5, for example, and wafer W having undergone the light exposure processing in light exposure device B6 may be transferred preferentially to the heating unit (PEB) within a prescribed period of time by delivery means 26. In this case, besides delivery means 26 in interface portion B5, a transfer arm dedicated to transfer via light exposure device B6→heating unit (PEB) may be provided.

Still further, in the substrate processing apparatus of the present invention, the plurality of process blocks may be configured to have internal process units of different kinds, different numbers and different layouts, as long as they have the same size in two dimensions. Furthermore, the processing of the same kind or the processing of different kinds may be carried out in the plurality of process blocks, as described above. It may be configured not to include a light exposure device, or it may be applied to processing using an interlayer insulating film, for example, or to processing of forming a SOG (Spin On Glass) film on the substrate. In the present invention, the substrate is not limited to the semiconductor wafer, but may be, e.g., a glass substrate for a liquid crystal display, or a photo-mask substrate.

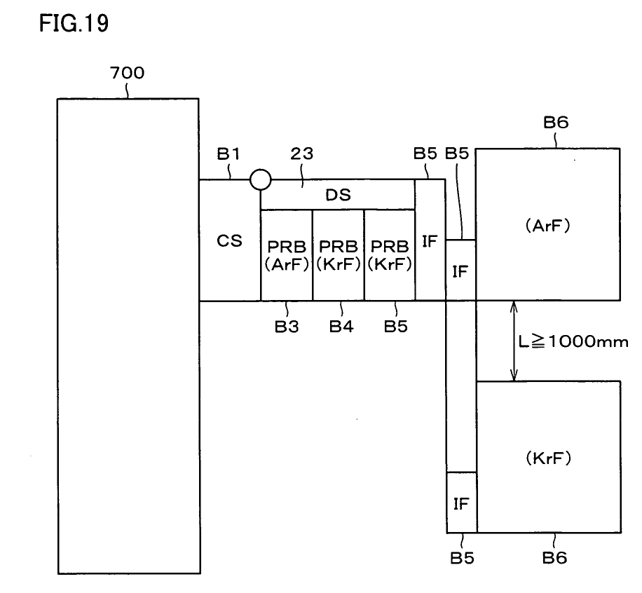

Further, it may be configured to include a plurality of light exposure devices. FIG. 19 shows an example for sharing the light exposure devices. Light exposure devices B6 include an ArF exposure machine and a KrF exposure machine, and a distance L between two light exposure devices B6 is not less than 1000 mm. Both light exposure devices B6 are connected to a coating and developing device via interface portion B5. A space permitting operation and maintenance is secured between light exposure devices B6. The exposure machines are capable of simultaneous processing, and process blocks B3, B4, B5 having PRB of coating and developing therefor are connected. When an EB (electron beam) exposure machine is connected as light exposure device B6 for production of various kinds of items with small quantities, parallel processing by the light exposure machines can realize improvement of TP (throughput). It is noted that in FIG. 19, the lots of wafers are introduced from a loading path 700 to carrier block B1 having a carrier station CS, and then introduced to process blocks B3, B4, B5 via second transfer means 23 incorporated in a docking station DS.

1. A substrate processing apparatus, comprising:
a carrier block including a carrier placement portion to/from which a substrate carrier storing a plurality of substrates is loaded/unloaded, and first transfer means for performing delivery of the substrate with respect to the substrate carrier placed on the carrier placement portion;
second transfer means provided adjacent to the carrier block and for transferring the substrate along a linear transfer path;
a first delivery stage for performing delivery of the substrate between said first transfer means and said second transfer means;
a plurality of process blocks arranged along said transfer path and freely attachable/detachable with respect to a main body of the apparatus; and
an interface portion located between said transfer path and a light exposure machine;
each process block including a coating unit for applying a resist solution to the substrate, a developing unit for performing developing processing on the substrate after exposure to light, a heating unit for heating the substrate, third transfer means for transferring the substrate between the units, and a second delivery stage for performing delivery of the substrate between said second transfer means and said third transfer means,
said transfer path extending from said interface portion to said carrier block, with said plurality of process blocks arranged on only one side of said transfer path, and each of said plurality of process blocks performing same processing, and
application of the resist solution to the substrate and/or the developing processing after exposure to light being performed in units of the respective process blocks.

2. The substrate processing apparatus according to claim 1, wherein an interface portion to which a light exposure device is connected is connected to a side of said transfer path opposite to a side connected to the carrier block.

3. The substrate processing apparatus according to claim 1, wherein an interface portion to which a light exposure device is connected is connected to a side of said transfer path opposite to a side connected to the process blocks.

4. A substrate processing apparatus, comprising:
a carrier block including a carrier placement portion to from which a substrate carrier storing a plurality of substrates is loaded/unloaded, and first transfer means for performing delivery of the substrate with respect to the substrate carrier placed on the carrier placement portion;
second transfer means provided adjacent to the carrier block and for transferring the substrate along a linear transfer path;
a first delivery stage for performing delivery of the substrate between said first transfer means and said second transfer means;
a plurality of process blocks arranged along said transfer path and freely attachable/detachable with respect to a main body of the apparatus; and
an interface portion located between said transfer path and a light exposure machine;
each process block including a liquid process unit performing processing with a chemical solution on the substrate, a heating unit for heating the substrate, third transfer means for transferring the substrate between the units, and a second delivery stage for performing delivery of the substrate between said second transfer means and said third transfer means,
said transfer path extending from said interface portion to said carrier block, with said plurality of process blocks arranged on only one side of said transfer path, and each of said plurality of process blocks performing same processing, and
processing being performed on the substrate in units of the respective process blocks.

5. The substrate processing apparatus according to claim 4, wherein said liquid process unit is for forming a coating film.

6. The substrate processing apparatus according to claim 4, wherein said liquid process unit is for applying a chemical solution including precursor of an insulating film to the substrate.

7. The substrate processing apparatus according to claim 4, wherein said plurality of process blocks are formed to have a same size in two dimensions.

8. The substrate processing apparatus according to claim 4, wherein said second transfer means is provided in a transfer block extending along arrangement of the plurality of process blocks and each process block is configured to be attachable/detachable with respect to the transfer block.

9. The substrate processing apparatus according to claim 8, wherein said carrier block is capable of rotating about a rotation shaft provided at an end portion of said transfer block.

10. The substrate processing apparatus according to claim 8, wherein said process block is attached to said transfer block via a hinge, and rotated about said hinge to be positioned in place.

11. The substrate processing apparatus according to claim 4, comprising a positioning member provided at a bottom portion or a side portion of a region where said process block is to be arranged, for use in positioning said process block.

12. The substrate processing apparatus according to claim 4, comprising a guide member provided at a bottom portion or a side portion of a region where said process block is to be arranged, for use in drawing the process block, and a positioning member provided for positioning the process block to the guide member.

13. The substrate processing apparatus according to claim 4, wherein each process block includes a plurality of utility lines for taking in utilities from the outside, and connection ends of the respective utility lines configured to be attachable/detachable with respect to connection ends of corresponding utility lines on the outside.

14. The substrate processing apparatus according to claim 13, wherein said plurality of utility lines supply utilities different from each other, and each of the plurality of utility lines is branched on a downstream side to be guided to the respective process units.

15. The substrate processing apparatus according to claim 13, wherein the plurality of utility lines include a supply line of liquid for temperature regulation, a supply line of inactive gas, an electric supply line, and a signal line.

16. The substrate processing apparatus according to claim 4, wherein a connection end on an external side is provided at a lower side of the second transfer means, and it is configured such that when the process block is pressed to the second transfer means side, the connection end on the external side is connected to a connection end on the process block side.

17. The substrate processing apparatus according to claim 16, wherein the utility lines further include a chemical solution supply tube.
